(19) United States
(12) Patent Application Publication
(10) Pub. No.: US 2026/0371518 A1
(43) Pub. Date: Nov. 19, 2026

(54) CHASSIS DEVICE CAPABLE OF ACCOMMODATING FANS OF DIFFERENT SIZES

(71) Applicant: Corsair Memory, Inc., Milpitas, CA (US)

(72) Inventors: Joseph Eamonn L. Clerkin, Milpitas, CA (US); Manny Melo, Milpitas, CA (US); Mitch Podlaha, Milpitas, CA (US)

(21) Appl. No.: 19/676,141

(22) Filed: May 13, 2026

(30) Foreign Application Priority Data
May 14, 2025 (TW) 114204813

(51) Int. Cl. H05K 7/20; H05K 7/18

(52) U.S. Cl. CPC H05K 7/20172; H05K 7/183

(57) ABSTRACT

comprises a main body unit, a first support unit, a second support unit, and a third support unit. The main body unit includes a main chassis structure. The first support unit includes at least one first support body and at least one first assembly structure. The second support unit includes at least one second support body and at least one second assembly structure. The second support body is a rail bracket oriented perpendicularly to the first support body. The second assembly structure is movably disposed within the first assembly structure to adjust the position of the second support body relative to the first support body. The third support unit includes at least one third support body for securing a fan.

### CROSS-REFERENCE TO RELATED APPLICATIONS

This application claims the benefit of priority to Taiwanese patent application no. 114204813 filed May 14, 2025 entitled “Chassis Device Capable of Accommodating Fans of Different Sizes”, the contents of which are incorporated herein by reference in their entirety for all purposes.

### FIELD OF THE INVENTION

The present invention relates to a chassis device, and more particularly, to a chassis device capable of accommodating fans of different sizes.

### BACKGROUND OF THE INVENTION

Fans are commonly installed in computer chassis to generate ventilation and dissipate heat generated by computer components. Currently, commercially available fan sizes include 120 mm×120 mm, 140 mm×140 mm, 160 mm×160 mm, 180 mm×180 mm, and 200 mm×200 mm. Furthermore, even fans of the same size manufactured by different manufacturers may have varying structural configurations, particularly with respect to the positions of the mounting holes, which may prevent a fan from being installed in the mounting holes of a given chassis.

In a conventional chassis, the mounting hole positions are fixed to secure computer components such as motherboards, power supply units, storage devices, and fans at predetermined locations. When the size of a user's fan does not match the fan size specified for the chassis, the fan often cannot be properly installed. If a user forces the fan into the chassis, typically only a single screw can be engaged, resulting in an insecure attachment and potential interference with other computer components.

Moreover, due to the compact interior of a computer chassis, multiple computer components are positioned in close proximity to one another, necessitating installation in a specific sequence. For example, if the motherboard and CPU cooling assembly are installed in the chassis first, the installation of a top-panel fan will be obstructed by the CPU cooling assembly. Accordingly, the top-panel fan must be installed before the other computer components can be assembled. Similarly, replacement of the top-panel fan requires removal of other components before the fan can be accessed.

Referring to FIG. 1, a conventional computer chassis 11 is illustrated. A static fan panel 12 is disposed within the computer chassis 11 and is immovable therein. The static fan panel 12 is provided with a plurality of mounting holes on its lateral sides to accommodate fans 13 of the various sizes described above.

Although the static fan panel 12 of the conventional computer chassis 11 can support fans 13 of multiple sizes, and the mounting holes on the lateral sides of the static fan panel 12 permit limited vertical repositioning of the fan 13, the airflow generated by the fan 13 is partially obstructed by the static fan panel 12. In addition, the fan 13 cannot be repositioned laterally. Accordingly, the existing computer chassis 11 suffers from the drawbacks of restricted fan repositioning and airflow obstruction.

In view of the foregoing, the known computer chassis structure exhibits the following deficiencies:

(1) Impaired heat dissipation efficiency:

In the conventional computer chassis 11, although the mounting holes are configured to accommodate fans 13 of different sizes, any displacement of the fan 13 causes the static fan panel 12 to partially obstruct the face of the fan 13, thereby impeding the airflow output and reducing heat dissipation efficiency.

(2) Difficulty in mounting fans of different specifications or manufacturers:

Since fans 13 produced by different manufacturers have differing structural configurations, including variations in the positions of the mounting holes on fans 13 of the same nominal size, it is often impossible to align the mounting holes of the fan 13 with the corresponding mounting holes of the computer chassis 11. Accordingly, conventional computer chassis suffer from the drawback of being incapable of reliably securing cooling fans of various manufacturers thereto.

(3) Installation interference preventing flexible assembly:

Due to the compact interior space of conventional computer chassis, a plurality of computer components are disposed in close proximity to one another, thereby requiring a user performing do-it-yourself (DIY) computer assembly to install said components in a predetermined sequence in order to avoid spatial interference therebetween. Failure to observe said sequence may render certain computer components impossible to install. Moreover, when replacement of any of said computer components is necessitated, corresponding disassembly of adjacent components must first be performed before the desired component within the chassis interior can be removed and reinstalled, thus precluding the user from freely and independently installing or removing any individual component at will. Accordingly, conventional computer chassis suffer from the drawback of requiring computer components to be installed and uninstalled in a strictly prescribed sequence.

There is accordingly a need in the art for a computer chassis that can accommodate fans 13 of various sizes, allows for free adjustment of fan position, and does not impede airflow.

### SUMMARY OF THE INVENTION

Some embodiments of the present invention provide a chassis device capable of accommodating fans of different sizes. The chassis device comprises a main body unit, a first support unit, and a second support uni.

The main body unit comprises a main chassis structure.

The first support unit comprises at least one first support body disposed on the main chassis structure, and at least one first assembly structure disposed on the first support body.

The second support unit comprises at least one second support body and at least one second assembly structure disposed on the second support body. The second support body is a rail bracket oriented perpendicularly to the first support body. The second assembly structure is movably disposed within the first assembly structure to allow adjustment of the position at which the second support body is fixed to the first support body.

The features of the present invention reside in that because the second assembly structure is movably disposed within the first assembly structure, the second support body can be repositioned relative to the first support body, enabling installation of fans of different sizes and lateral adjustment of fan position. The third support body, being movably disposed on the second support body, additionally provides vertical adjustment of fan position. Users can select a fan of appropriate size for installation in the main chassis structure. Furthermore, since the second support body is an elongated rail bracket, it does not obstruct the airflow of the fan regardless of how the fan's position is adjusted.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a partial perspective view of a prior art computer chassis.

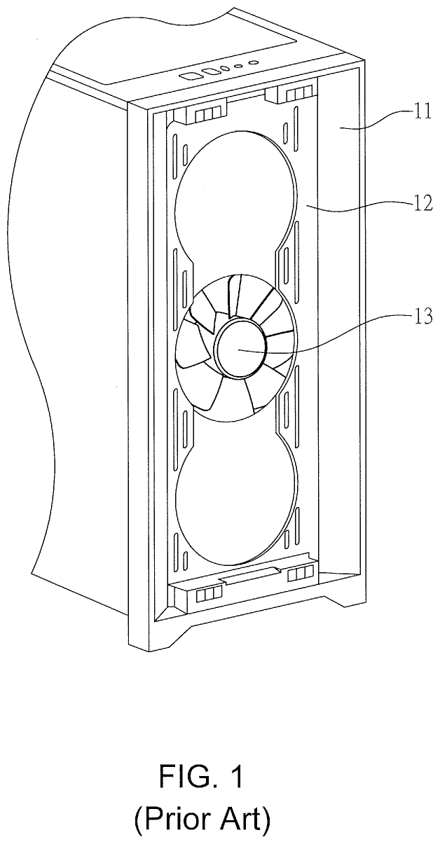

FIG. 2 is a front view of a chassis device capable of accommodating fans of different sizes according to a first embodiment of the present invention.

FIG. 3 is a front view illustrating an alternative fan size configuration in the first embodiment.

FIG. 4 is a front view illustrating another fan size configuration in the first embodiment.

FIG. 5 is a partial front view of a chassis device capable of accommodating fans of different sizes according to a second embodiment of the present invention.

FIG. 6 is a partial front view of a second support unit according to the second embodiment.

FIG. 7 is a partial perspective view of a third support body and a second support body according to the second embodiment.

FIG. 8 is a perspective view of a chassis device capable of accommodating fans of different sizes according to a third embodiment of the present invention.

FIG. 9 is a top view of a chassis device capable of accommodating fans of different sizes according to a fourth embodiment of the present invention.

FIG. 10 is a partial perspective view of a second support body and a third support body according to the fourth embodiment.

### DETAILED DESCRIPTION OF THE PREFERRED EMBODIMENTS

Hereinafter, the present embodiment will be described in detail with appropriate reference to the drawings. In the drawings used in the following description, there are cases where characteristic portions are enlarged for convenience to make it easier to understand features of the present invention, and dimensional ratios of each component may differ from the actual ones. Materials, dimensions, and the like exemplified in the following description are examples, and the present invention is not limited thereto and can be implemented with appropriate modifications within a scope of the present invention.

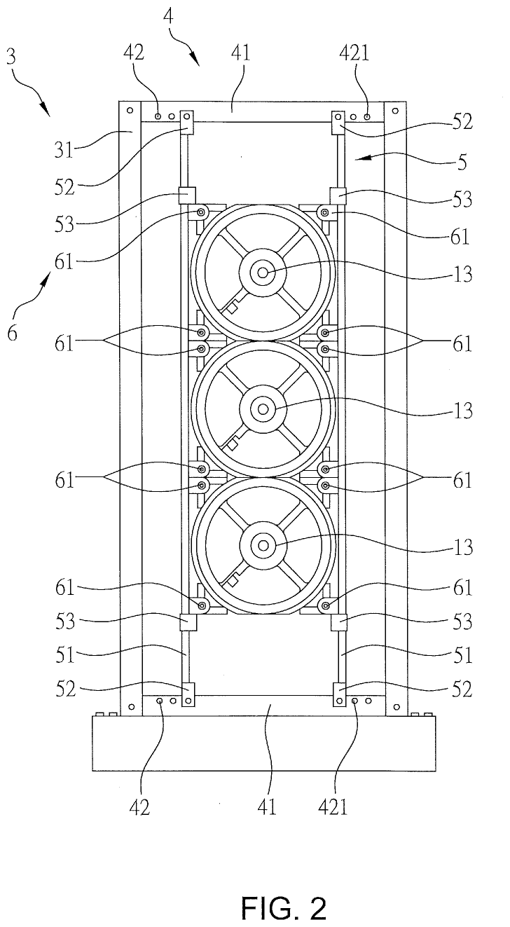

Referring to FIG. 2, a chassis device capable of accommodating fans of different sizes according to a first embodiment of the present invention is illustrated. The chassis device comprises a main body unit 3, a first support unit 4, a second support unit 5, and a third support unit 6.

The main body unit 3 comprises a main chassis structure 31, which serves as the support frame within a standard computer chassis.

The first support unit 4 comprises two first support bodies 41 disposed on the main chassis structure 31, and two first assembly structures 42 respectively disposed on the two first support bodies 41. The two first support bodies 41 are rail brackets disposed in parallel and spaced apart from each other. In some embodiments, the two first support bodies 41 are plate-type brackets disposed on the front panel of the main chassis structure 31 and arranged horizontally at the bottom and top portions of the front panel, respectively. In some embodiments, the number of first support bodies 41 and first assembly structures 42 may be one, and the invention is not so limited. The two first support bodies 41 are metal-sheet support members fixed to the main chassis structure 31 by one or more fastening methods including, but not limited to, screws, welding, or rivets.

The second support unit 5 comprises two second support bodies 51 and a plurality of second assembly structures 52 spaced apart on the two second support bodies 51. Each second support body 51 is a slender rail bracket oriented perpendicularly to the first support body 41. The second assembly structure 52 is movably disposed within the first assembly structure 42 to allow adjustment of the position at which the second support body 51 is fixed to the first support body 41. The plurality of second assembly structures 52 are disposed at the top and bottom ends of the two second support bodies 51, respectively. In some embodiments, the number of second support bodies 51 may be one or more than two, and the number of second assembly structures 52 on each second support body 51 may also be one, and the invention is not so limited.

The third support unit 6 comprises a plurality of third support bodies 61 movably disposed on the second support body 51. The plurality of third support bodies 61 are used to secure the fan 13. Each third support body 61 is a conventional screw-type mounting bracket configured to fix the fan 13 using screws. In some embodiments, the number of third support bodies 61 on the second support body 51 may also be one, and the invention is not so limited.

In some embodiments, the two first assembly structures 42 each have a plurality of first circular holes 421 spaced apart on the respective first support bodies 41. The plurality of first circular holes 421 are arranged in a lateral row. A single second assembly structure 52 is fixed within a single first circular hole 421. In some embodiments, each first support body 41 is provided with six first circular holes 421, with three first circular holes 421 disposed on the left side of the first support body 41 and three first circular holes 421 disposed on the right side of the first support body 41.

As shown in FIG. 2, the plurality of second assembly structures 52 of the two second support bodies 51 are respectively secured to the two innermost first circular holes 421 of the two first support bodies 41, thereby positioning the plurality of third support bodies 61 at a spacing suitable for fixing 120 mm×120 mm fans 13. In this configuration, twelve third support bodies 61 are used, with four third support bodies 61 securing one fan unit, for a total of three 120 mm×120 mm fan units. In some embodiments, additional first circular holes 421 may be provided on the two first support bodies 41 to permit lateral adjustment of the second assembly structures 52 before locking, enabling users to adjust the lateral position of the fans 13.

The second support unit 5 further comprises a plurality of stoppers 53 fixed to the second support body 51. The plurality of stoppers 53 are disposed above and below the plurality of third support bodies 61 to fix the vertical positions of the third support bodies 61 and thereby fix the height of the fan 13. The height of the plurality of stoppers 53 on the second support body 51 is adjustable, thereby enabling adjustment of the fan height. In addition, the plurality of stoppers 53 may also be disposed between the plurality of third support bodies 61 to adjust the spacing between adjacent fans 13. In some embodiments, the second support body 51 may be configured without stoppers 53, and the invention is not so limited.

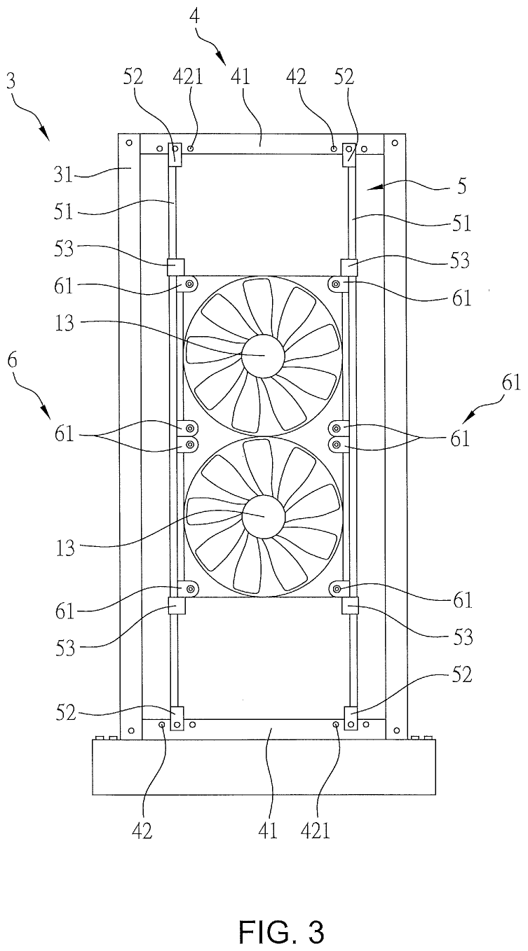

Referring to FIG. 3, in some embodiments, the plurality of second assembly structures 52 are secured to the second first circular holes 421 from the left and the second first circular hole 421 from the right on the first support body 41, respectively, positioning the plurality of third support bodies 61 at a spacing suitable for fixing 140 mm×140 mm fans 13. Two sets of 140 mm×140 mm fans 13 are disposed between the two second support bodies 51.

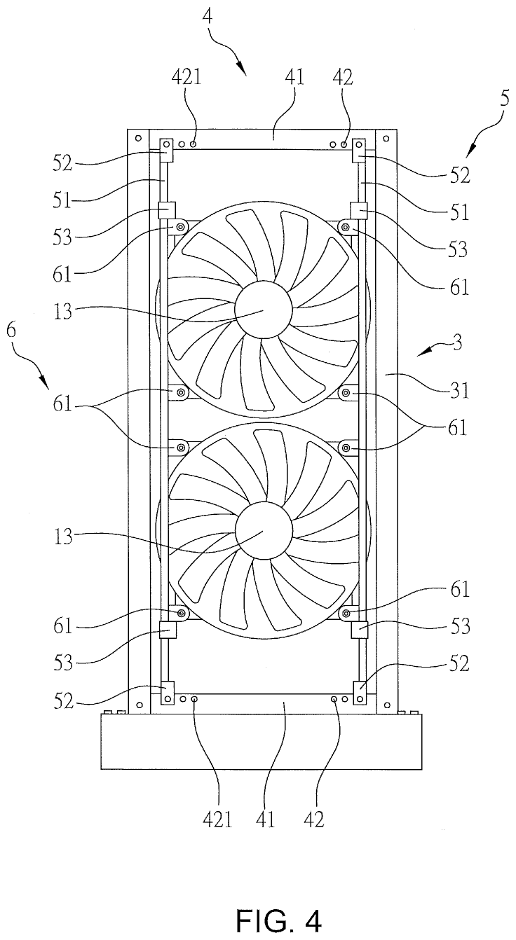

Referring to FIG. 4, in some embodiments, the plurality of second assembly structures 52 are secured to the outermost first circular holes 421 on both the left and right sides, respectively, positioning the plurality of third support bodies 61 at a spacing suitable for fixing 200 mm×200 mm fans 13. Two sets of 200 mm×200 mm fans 13 are disposed between the two second support bodies 51.

In some embodiments, the two second support bodies 51 are slender rail brackets. Regardless of which size of fan 13 is installed, or how the vertical or lateral position of the fan 13 is adjusted, the two second support bodies 51 do not obstruct the airflow of the fan 13. The present invention therefore not only accommodates fans 13 of different sizes, but also enables users to adjust fan position without impeding airflow.

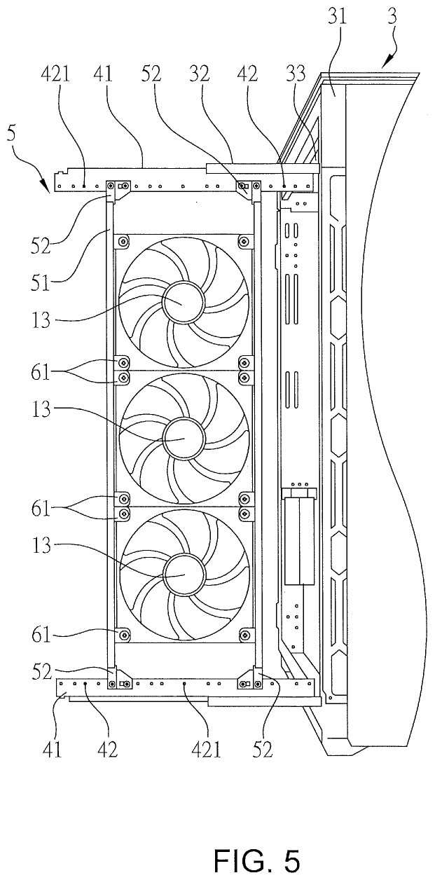

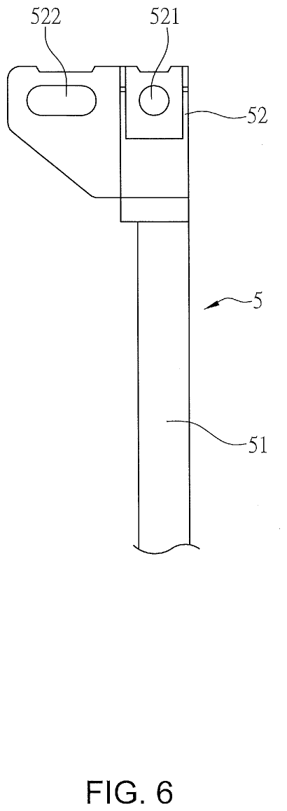

Referring to FIGS. 5 and 6, a chassis device capable of accommodating fans of different sizes according to a second embodiment of the present invention is illustrated. The second embodiment is substantially the same as the first embodiment and the similarities will not be reiterated. The difference resides in that the second assembly structure 52 of the second embodiment is provided with a second circular hole 521 and a second elongated hole 522, both of which are connected to the first assembly structure 42.

In some embodiments, the first assembly structure 42 has an increased number of first circular holes 421 on the first support body 41. The second circular hole 521 allows a screw to be secured within one of the first circular holes 421 to fix the position of the second support body 51, while the second elongated hole 522 allows a screw to be secured within another first circular hole 421 to provide an additional fixing point for the second support body 51.

As shown in FIG. 6, the second elongated hole 522 extends in the lateral direction, while the rail bracket of the second support body 51 extends in the longitudinal direction, such that the opening extension direction of the second elongated hole 522 is perpendicular to the extension direction of the rail bracket of the second support body 51. When the second assembly structure 52 uses a screw to fix the second circular hole 521 in one of the first circular holes 421, another first circular hole 421 is exposed within the second elongated hole 522 to provide an additional screw-fixing location.

In some embodiments, three second support bodies 51 are disposed between the two first support bodies 41, with one second support body 51 positioned between the other two. The three second support bodies 51 together support two rows of fans 13, accommodating a total of eight 120 mm×120 mm fan units.

Referring again to FIG. 5, the main body unit 3 further comprises a slide rail structure 32 disposed on the main chassis structure 31. The slide rail structure 32 is connected to one of the first support bodies 41 to allow that first support body 41 to move relative to the main chassis structure 31. In some embodiments, two slide rail structures 32 may be provided on the main chassis structure 31 to connect the two first support bodies 41 individually, and the invention is not so limited.

The slide rail structure 32 is of the same type as commercially available drawer slides and will not be described further. The main body unit 3 further comprises a side opening 33 disposed on a lateral side of the main chassis structure 31, through which the slide rail structure 32 can slide outward. When the slide rail structure 32 slides outward through the side opening 33, the first support unit 4, the second support unit 5, the third support unit 6, and the fan 13 are displaced outward from the main chassis structure 31, allowing the user to conveniently adjust the position of the second support body 51 on the first support body 41, adjust the position of the third support body 61 on the second support body 51, and install or remove the fan 13. Upon completion of fan installation, the slide rail structure 32 is slid back into the main chassis structure 31 through the side opening 33, bringing the first support unit 4, the second support unit 5, the third support unit 6, and the fan 13 back into the main chassis structure 31.

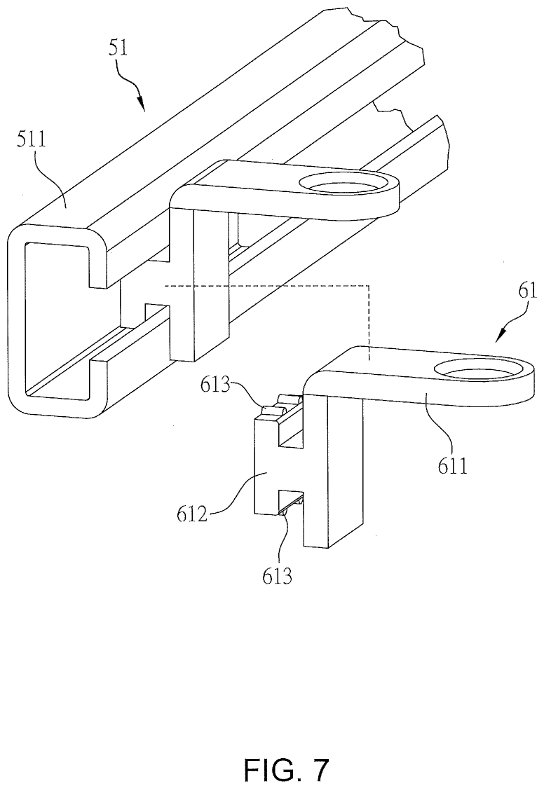

Referring to FIG. 7, the third support body 61 comprises a fan fixing member 611, a bracket fixing member 612 connected to the fan fixing member 611, and a plurality of elastic fixing members 613 disposed on the bracket fixing member 612. The bracket fixing member 612 is generally T-shaped. The plurality of elastic fixing members 613 respectively bear against the second support body 51. The second support body 51 has a concave elongated track 511 connected to the plurality of third support bodies 61, and the plurality of elastic fixing members 613 are located within the concave elongated track 511.

The concave elongated track 511 is a C-type channel rail. The bracket fixing member 612 is disposed within the interior of the concave elongated track 511. The concave elongated track 511 is provided with a retaining feature configured to prevent the bracket fixing member 612 from falling out of the concave elongated track 511. The plurality of elastic fixing members 613 are elastic anti-slip rubber members disposed on the lateral sides of the bracket fixing member 612. The plurality of elastic fixing members 613 bear against the inner wall of the concave elongated track 511 to provide an anti-slip effect, thereby preventing the third support body 61 from sliding off the second support body 51.

The fan fixing member 611 is generally L-shaped and is provided with a threaded hole for securing the fan 13 with a screw. In some embodiments, the fan fixing member 611 may be generally T-shaped and provided with two threaded holes for securing two fans 13 with two screws.

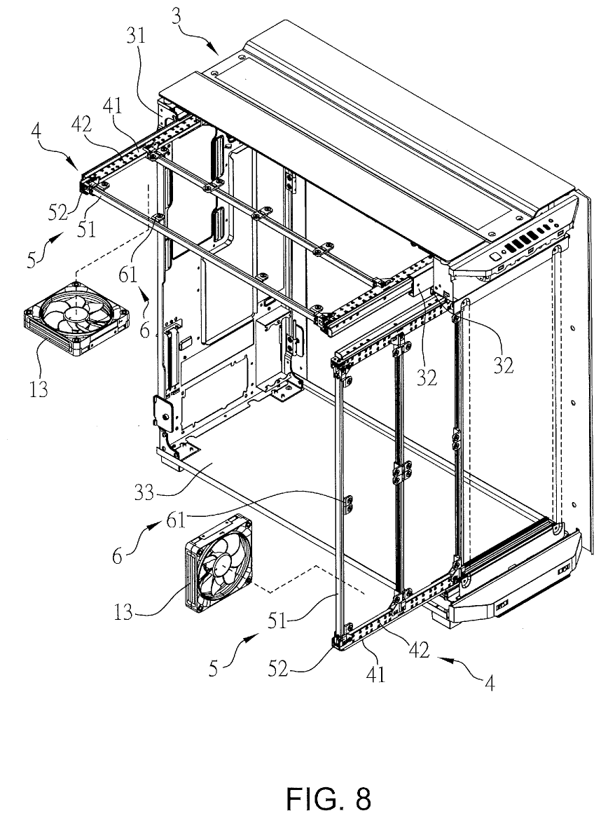

Referring to FIG. 8, a chassis device capable of accommodating fans of different sizes according to a third embodiment of the present invention is illustrated. The third embodiment is substantially the same as the second embodiment and the similarities will not be reiterated. The difference resides in that the main chassis structure 31 of the third embodiment is provided with a slide rail structure 32, a first support unit 4, a second support unit 5, a third support unit 6, and at least one fan 13 in each of the front panel and the top panel. The dashed lines in FIG. 8 indicate the support frame disposed within the front panel of the main chassis structure 31.

In some embodiments, two slide rail structures 32 are disposed at spaced intervals on the top panel of the main chassis structure 31. The two slide rail structures 32 are connected to a first support body 41 each, with the two first support bodies 41 positioned at the top and bottom, respectively. The second support unit 5 has three second support bodies 51 disposed between the two first support bodies 41. The third support unit 6 has a plurality of third support bodies 61 disposed on the three second support bodies 51 for securing a plurality of fans 13.

In some embodiments, the plurality of second support bodies 51 between the two first support bodies 41 can be arranged in multiple configurations to accommodate commercially available all-in-one liquid cooling systems, for example, all-in-one liquid cooling systems in standard 120 mm, 240 mm, 360 mm, and 480 mm formats can be directly installed in the chassis device.

Because the slide rail structure 32 can bring the first support unit 4, the second support unit 5, and the third support unit 6 to slide outward through the side opening 33 of the main chassis structure 31, fan installation is highly convenient and does not interfere with other computer components inside the main chassis structure 31. Fans can be installed at any time without the need to first remove the motherboard or other internal computer components. The present invention thus provides the features that fan installation does not require prior removal of internal computer components.

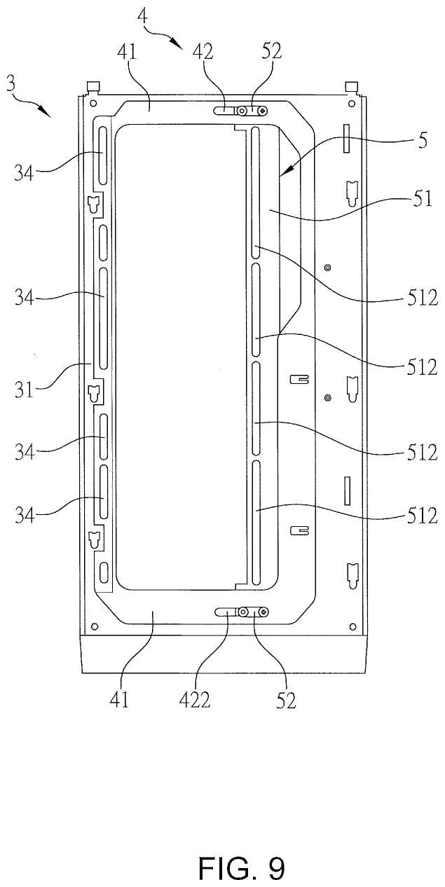

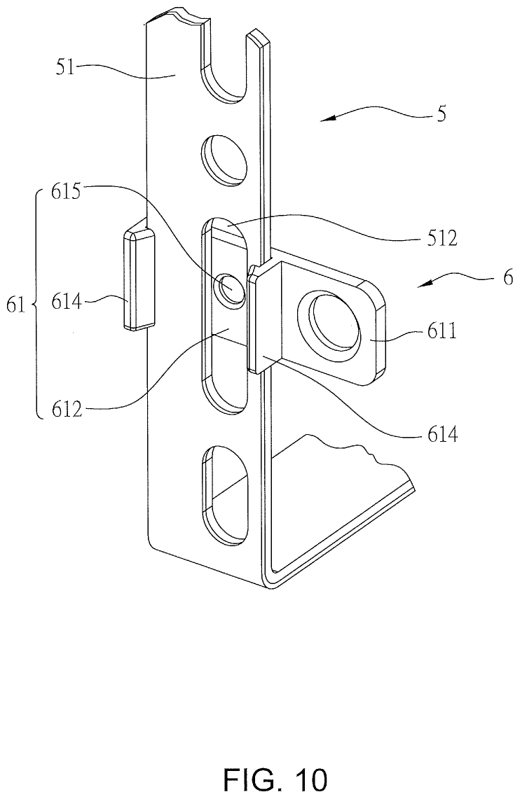

Referring to FIGS. 9 and 10, a chassis device capable of accommodating fans of different sizes according to a fourth embodiment of the present invention is illustrated. The fourth embodiment is substantially the same as the first embodiment and the similarities will not be reiterated. The difference resides in that the first support unit 4, the second support unit 5, and the third support unit 6 of the fourth embodiment are disposed on the top surface of the main chassis structure 31, and only one second support body 51 is disposed between the two first support bodies 41.

The main body unit 3 further comprises a chassis assembly structure 34 disposed on the left side of the main chassis structure 31. The chassis assembly structure 34 is fixedly mounted within the main chassis structure 31 and is immovable. In some embodiments, the chassis assembly structure 34 takes the form of a plurality of elongated slot openings, but is not limited thereto.

Each first assembly structure 42 has a first elongated hole 422 disposed on the respective first support body 41. One first elongated hole 422 is provided respectively at the upper and lower sides of the top surface of the main chassis structure 31. In some embodiments, each first assembly structure 42 may be provided with a plurality of first elongated holes 422, or only one first elongated hole 422 may be provided on the main chassis structure 31, and the invention is not so limited.

The rail bracket of the second support body 51 extends in the longitudinal direction. The first elongated hole 422 extends in the lateral direction, such that the extension direction of the first elongated hole 422 is perpendicular to the extension direction of the rail bracket of the second support body 51. The second assembly structure 52 is movably fixed within the first elongated hole 422 to allow lateral adjustment of the position of the second support body 51.

The second support body 51 has a perforated elongated track 512, which extends in the same longitudinal direction as the rail bracket of the second support body 51, such that the longitudinal direction of the perforated elongated track 512 is parallel to the extension direction of the rail bracket of the second support body 51. The third support body 61 is movably disposed on the second support body 51.

The third support body 61 comprises a fan fixing member 611, a bracket fixing member 612 connected to the fan fixing member 611, two side stoppers 614 spaced apart on the bracket fixing member 612, and a locking member 615 disposed on the bracket fixing member 612. The locking member 615 and the second support body 51 are disposed between the two side stoppers 614.

In some embodiments, the fan fixing member 611 and the bracket fixing member 612 are formed from a single plate body. The two side stoppers 614 are perpendicular to the bracket fixing member 612. The fan fixing member 611 is provided with mounting holes for securing the fan 13. The locking member 615 is a hole formed in the bracket fixing member 612. The two side stoppers 614 clamp the second support body 51 and align the locking member 615 with the perforated elongated track 512. A screw can then be used to fasten the locking member 615 and the perforated elongated track 512 together, thereby securing the third support body 61 to the second support body 51.

The chassis assembly structure 34 disposed on the main chassis structure 31 cooperates with the third support body 61 disposed on the second support body 51 to fix the fan 13 to the top surface of the main chassis structure 31. By adjusting the position of the second assembly structure 52 within the first assembly structure 42, the distance between the chassis assembly structure 34 and the third support body 61 can be varied to accommodate fans 13 of different sizes.

As shown in FIG. 9, although the lateral position of the fan 13 within the main chassis structure 31 cannot be adjusted because the position of the chassis assembly structure 34 is fixed, the perforated elongated track 512 of the second support body 51 and the chassis assembly structure 34, which takes the form of a plurality of elongated slot openings, allow users to adjust the longitudinal position of the fan 13 within the main chassis structure 31.

From the foregoing description, the chassis device capable of accommodating fans of different sizes of the present invention provides the following features:

(1) Easy adjustment of fan positions without obstructing airflow:

The second assembly structure 52 is movably disposed within the first assembly structure 42, enabling users to install fans 13 of different sizes and to freely reposition the fan 13 laterally. Additionally, since the second support body 51 is a slender rail bracket, it does not impede the airflow output by the fans 13 regardless of how the fan position is adjusted.

(2) Fine-tuning capability to match diverse fan mounting configurations:

When the first assembly structure 42 employs the first elongated hole 422, or the second assembly structure 52 employs the second elongated hole 522, the second support body 51 can be fine-tuned in position relative to the first support body 41. In combination with the ability of the third support body 61 to be freely repositioned on the second support body 51, the second support body 51 can be adjusted to a position that secures the fan 13 even when fans 13 of the same nominal size have differing mounting hole patterns.

(3) Convenient installation and removal of fans:

When the slide rail structure 32 slides outward through the side opening 33, the first support unit 4, the second support unit 5, the third support unit 6, and the fan 13 are displaced outside the main chassis structure 31, facilitating fan position adjustment without interference from the main chassis structure 31. Upon completion of fan installation, the slide rail structure 32 is slid back into the main chassis structure 31 to complete the installation of the fan 13. By employing the slide rail structure 32, installation and removal of the fan 13 does not interfere with other computer components inside the chassis, and the fan 13 can be installed at any time without the need to remove other computer components.

In summary, the second assembly structure 52 is movably disposed within the first assembly structure 42 to permit installation of fans 13 of various sizes and lateral adjustment of fan position. The third support body 61 is movably disposed on the second support body 51 to permit longitudinal adjustment of fan position. The slide rail structure 32 can displace the first support unit 4, the second support unit 5, the third support unit 6, and the fan 13 to the outside of the main chassis structure 31, facilitating fan installation. The plurality of elastic fixing members 613 bear against the inner wall of the concave elongated track 511 to generate friction and thereby provide an anti-slip effect. Furthermore, after the locking member 615 is aligned with the perforated elongated track 512, a screw can be used to fasten the locking member 615 and the perforated elongated track 512 together, enabling the third support body 61 to secure the fan 13 in position and support its weight.

The foregoing outlines features of several embodiments so that those skilled in the art may better understand the aspects of the present invention. Those skilled in the art should appreciate that they may readily use the present invention as a basis for designing or modifying other processes and structures for carrying out the same purposes and/or achieving the same advantages of the embodiments introduced herein. Those skilled in the art should also realize that such equivalent constructions do not depart from the spirit and scope of the present invention, and that they may make various changes, substitutions, and alterations herein without departing from the scope of the present invention.

We claim:

1. A chassis device capable of accommodating fans of different sizes, comprising:
a main body unit (3), comprising a main chassis structure (31);
a first support unit (4), comprising at least one first support body (41) arranged on the main chassis structure (31), and at least one first assembly structure (42) arranged on the first support body (41); and
a second support unit (5), comprising at least one second support body (51), and at least one second assembly structure (52) arranged on the second support body (51), wherein the second support body (51) is a rail bracket oriented perpendicularly to the first support body (41), and the second assembly structure (52) is movably arranged within the first assembly structure (42) to adjust the position at which the second support body (51) is fixed to the first support body (41).

2. The chassis device capable of accommodating fans of different sizes as claimed in claim 1, wherein the first assembly structure (42) has a plurality of first circular holes (421) spaced apart on the first support body (41), and the second assembly structure (52) is fixed on one of the first circular holes (421).

3. The chassis device capable of accommodating fans of different sizes as claimed in claim 1, wherein the first assembly structure (42) has at least one first elongated hole (422) arranged on the first support body (41), the opening extension direction of the first elongated hole (422) being perpendicular to the extension direction of the rail bracket of the second support body (51), and the second assembly structure (52) being movably fixed on the first elongated hole (422).

4. The chassis device capable of accommodating fans of different sizes as claimed in claim 1, wherein the second assembly structure (52) has a second circular hole (521) connected to the first assembly structure (42).

5. The chassis device capable of accommodating fans of different sizes as claimed in claim 1, wherein the second assembly structure (52) has a second elongated hole (522) connected to the first assembly structure (42), the opening extension direction of the second elongated hole (522) being perpendicular to the extension direction of the rail bracket of the second support body (51).

6. The chassis device capable of accommodating fans of different sizes as claimed in claim 1, further comprises a third support unit (6), wherein the third support unit (6) comprises at least one third support body (61) movably arranged on the second support body (51), and the third support body (61) is configured to secure a fan.

7. The chassis device capable of accommodating fans of different sizes as claimed in claim 6, wherein the third support body (61) comprises a fan fixing member (611), a bracket fixing member (612) connected to the fan fixing member (611), and a plurality of elastic fixing members (613) arranged on the bracket fixing member (612), the plurality of elastic fixing members (613) respectively bearing against the second support body (51), wherein the second support body (51) has a concave elongated track (511) connected to the third support body (61), and the plurality of elastic fixing members (613) are located within the concave elongated track (511).

8. The chassis device capable of accommodating fans of different sizes as claimed in claim 6, wherein the third support body (61) comprises a fan fixing member (611), a bracket fixing member (612) connected to the fan fixing member (611), two side stoppers (614) spaced apart on the bracket fixing member (612), and a locking member (615) arranged on the bracket fixing member (612), wherein the locking member (615) and the second support body (51) are arranged between the two side stoppers (614).

9. The chassis device capable of accommodating fans of different sizes as claimed in claim 6, wherein the second support body (51) has at least one perforated elongated track (512) connected to the third support body (61), and the extension direction of the perforated elongated track (512) being parallel to the extension direction of the rail bracket of the second support body (51).

10. The chassis device capable of accommodating fans of different sizes as claimed in claim 1, wherein the main body unit (3) further comprises at least one slide rail structure (32) arranged on the main chassis structure (31), and connected to the first support body (41), whereby the first support body (41) is movable relative to the main chassis structure (31).
